(19) United States
(12) Patent Application Publication
(10) Pub. No.: US 2026/0107815 A1
(43) Pub. Date: Apr. 16, 2026

(54) SEMICONDUCTOR PACKAGE

(71) Applicant: Samsung Electronics Co, Ltd., Suwon-si (KR)

(72) Inventors: Donghun Lee, Suwon-si (KR); Seungduk Baek, Suwon-si (KR)

(73) Assignee: Samsung Electronics Co, Ltd., Suwon-si (KR)

(21) Appl. No.: 19/093,062

(22) Filed: Mar. 27, 2025

(30) Foreign Application Priority Data
Oct. 10, 2024 (KR) 10-2024-0138024

(51) Int. Cl. H01L 23/00; H01L 23/538; H01L 25/18; H10B 80/00; H10D 80/30

(52) U.S. Cl. CPC H10W 72/90; H10W 70/611; H10W 90/00; H10W 90/401; H10B 80/00; H10D 80/30; H10W 72/932; H10W 72/934; H10W 90/24; H10W 90/297; H10W 90/724; H10W 90/792

(57) ABSTRACT

Provided is a semiconductor package. The semiconductor package may include: a first semiconductor chip having a device region and a dummy region surrounding the device region in a planar view, second semiconductor chips on an upper surface of the device region of the first semiconductor chip, and a molding layer covering the second semiconductor chips on the first semiconductor chip, wherein the first semiconductor chip includes a first semiconductor substrate, a first lower pad arranged on a lower surface of the first semiconductor substrate, a first upper insulating layer including a first insulating layer and a second insulating layer and being arranged on an upper portion of the first semiconductor substrate, and a first upper pad and a trench region, which are arranged within the second insulating layer.

### CROSS-REFERENCE TO RELATED APPLICATIONS

This present application claims priority to and the benefit under 35 U.S. C. § 119(a)-(d) of Korean Patent Application No. 10-2024-0138024, filed on Oct. 10, 2024, in the Korean Intellectual Property Office, the entire disclosure of which is incorporated herein by reference.

### BACKGROUND

The inventive concepts relate to a semiconductor package, and more specifically, to a semiconductor package including stacked semiconductor chips.

A semiconductor package is an integrated circuit chip implemented in a form suitable for use in an electronic product. Typically, in a semiconductor package, after mounting semiconductor chips on a printed circuit board, the semiconductor chips are electrically connected using bonding wires or bumps. With the development of the electronics industry, it may be required that a semiconductor package implements high-capacity characteristics. In addition, as electronic products become miniaturized, the demand for smaller semiconductor packages is increasing.

### SUMMARY

The inventive concepts provide a semiconductor package having improved reliability.

In addition, the problems to be solved by the technical spirit of the present inventive concepts are not limited to the problems mentioned herein, and other problems not mentioned will be clearly understood by those skilled in the art from the description herein.

According to some aspects, there is provided a first semiconductor chip that may have: a device region and a dummy region surrounding the device region in a planar view, one or more second semiconductor chips on an upper surface of the device region of the first semiconductor chip, and a molding layer covering at least a portion of the one or more second semiconductor chips on the first semiconductor chip, wherein the first semiconductor chip includes a first semiconductor substrate, a first lower pad arranged on a lower surface of the first semiconductor substrate, a first upper insulating layer including a first insulating layer and a second insulating layer and being arranged on an upper portion of the first semiconductor substrate, and a first upper pad and a trench region which are arranged within the second insulating layer.

According to some aspects, there is provided a semiconductor package that may include: a first semiconductor chip, second semiconductor chips on an upper surface of the first semiconductor chip, and a molding layer covering at least a portion of the second semiconductor chips on the first semiconductor chip, wherein the first semiconductor chip includes, a first semiconductor substrate, a first upper insulating layer including a first insulating layer and a second insulating layer arranged on an upper surface of the first semiconductor substrate, a first upper pad arranged within the second insulating layer, a first lower pad arranged on a lower surface of the first semiconductor substrate, and a trench region arranged within the second insulating layer, wherein each of the second semiconductor chips includes a second semiconductor substrate, a second lower pad arranged on a lower surface of the second semiconductor substrate, and a second upper pad arranged on an upper portion of the second semiconductor substrate, and wherein a width in a horizontal direction of the second semiconductor chip is less than a longest width in the horizontal direction of the trench region.

According to some aspects, there is provided a semiconductor package that may include: a first semiconductor chip comprising: a first semiconductor substrate, a first upper insulating layer including a first insulating layer and a second insulating layer and disposed on an upper surface of the first semiconductor substrate, a first through-via passing through the first semiconductor substrate, a first wiring pattern electrically connected to the first through-via and disposed within the first insulating layer, a first upper pad disposed within the second insulating layer and electrically connected to the first wiring pattern, a trench region disposed within the second insulating layer, and a first lower pad disposed on a lower surface of the first semiconductor substrate, second semiconductor chips on an upper surface of the first semiconductor chip, each of the second semiconductor chips including a second semiconductor substrate, a second upper insulating layer disposed on an upper surface of the second semiconductor substrate, a second lower insulating layer disposed on a lower surface of the second semiconductor substrate, a second upper pad disposed within the second upper insulating layer, and a second lower pad disposed within the second lower insulating layer, a molding layer covering one or more sidewalls of the second semiconductor chips on the first semiconductor chip, and a lower bump provided on a lower surface of the first semiconductor chip and electrically connected to the first lower pad, wherein, in a planar view, when a region of the trench region that overlaps the second semiconductor chip is referred to as a first region and a region that does not overlap the second semiconductor chip is referred to as a second region, the trench region has a step-like structure in which vertical levels of the first region and the second region are different from each other, and wherein a vertical length of the second region is 1 μm, and a vertical length of the first region is less than half the vertical length of the second region.

According to some aspects, there is provided a semiconductor package manufacturing method which may include a step of providing one or more second semiconductor chips on a first semiconductor chip and a step of bonding the first semiconductor chip and a lowermost one of the one or more second semiconductor chips, wherein the first semiconductor chip may include: a first semiconductor substrate; a first upper insulating layer arranged on an upper surface of the first semiconductor substrate; a first upper pad arranged within the first upper insulating layer; a first lower pad arranged on a lower surface of the first semiconductor substrate; and a trench region which may be arranged within the first upper insulating layer.

In some embodiments, the trench region may have a first portion positioned laterally inside the periphery of the second semiconductor chip and a second portion positioned laterally outside the periphery of the second semiconductor chip, and the first portion of the trench region may have a first depth and the second portion of the trench region may have a second depth, wherein the first depth is less than the second depth.

In some embodiments, the trench region may have a variable depth that increases moving laterally from an inner edge of the trench region toward an outer edge of the trench region, and wherein the trench region is positioned to be laterally overlapping with the periphery of the second semiconductor chip.

In some embodiments, each of the one or more second semiconductor chips may include: a second semiconductor substrate; a second lower pad arranged on a lower surface of the second semiconductor substrate; and a second upper pad arranged on an upper portion of the second semiconductor substrate. In some embodiments, the bonding may include a hybrid bonding process.

In some embodiments, the method may further include providing a molding layer covering at least a portion of the one or more second semiconductor chips on the first semiconductor chip.

### BRIEF DESCRIPTION OF THE DRAWINGS

Embodiments will be more clearly understood from the following detailed description taken in conjunction with the accompanying drawings in which:

FIG. 1 is a plan view illustrating a semiconductor package according to embodiments;

FIG. 2 is a cross-sectional view taken along line I-I′ of FIG. 1, according to embodiments;

FIG. 3 is a diagram showing an enlarged view of a region II of FIG. 2, according to embodiments;

FIG. 4 is diagram showing an enlarged view of the region II of FIG. 2, according to embodiments;

FIG. 5 is another diagram showing an enlarged view of the region II of FIG. 2, according to embodiments;

FIG. 6 is a diagram showing an enlarged view of a region III of FIG. 2, according to embodiments;

FIG. 7 is a diagram showing an enlarged view of a region A of FIG. 3, according to embodiments;

FIGS. 8 to 10 are diagrams showing enlarged views of the region A of FIG. 3, according to embodiments;

FIG. 11 is a plan view illustrating a trench region included in a semiconductor package, according to embodiments;

FIGS. 12 to 15 are plan views illustrating a trench region according to embodiments; and

FIG. 16 is a cross-sectional view illustrating a semiconductor package according to embodiments.

### DETAILED DESCRIPTION

The inventive concepts may be modified into various forms and may have various embodiments. In this regard, the inventive concepts will now be described in detail in relation to embodiments, examples of which are illustrated in the accompanying drawings. However, this is not intended to limit the present embodiments to a specific disclosure form. The embodiments of the inventive concepts are capable of various modifications and may be embodied in many different forms.

All examples or example terms are simply used to explain in detail the technical scope of the present disclosure, and thus, the scope of the present disclosure is not limited by the examples or the example terms as long as it is not defined by the claims.

Unless otherwise specifically stated, in this specification, the vertical direction is defined as a Z direction, and a first horizontal direction and a second horizontal direction may be defined as horizontal directions perpendicular to the Z direction, respectively. The first horizontal direction may be referred to as an X direction, and the second horizontal direction may be referred to as a Y direction. A vertical level may refer to a height level in the vertical direction (e.g., Z direction). A horizontal width of the first horizontal direction may refer to a length in the horizontal direction (e.g., X direction and/or Y direction), and a vertical length may refer to a length in the vertical direction (e.g., Z direction).

As described herein, a semiconductor package having improved reliability is provided. In some circumstances, one or more semiconductor chips of semiconductor packages may be affected by warpage due to biasing of metal parts therein. As an example, during an annealing process, warpage of metal wiring can be caused. Such warpage can affect bonding processes, thereby leading to undesired defects including cracks. The inventors have recognized that such undesired effects can be prevented by incorporating one or more trench regions in the semiconductor package. With one or more trenches formed therein, the semiconductor package may have improved reliability since bonding defects and/or crack defects caused by warpage can be mitigated.

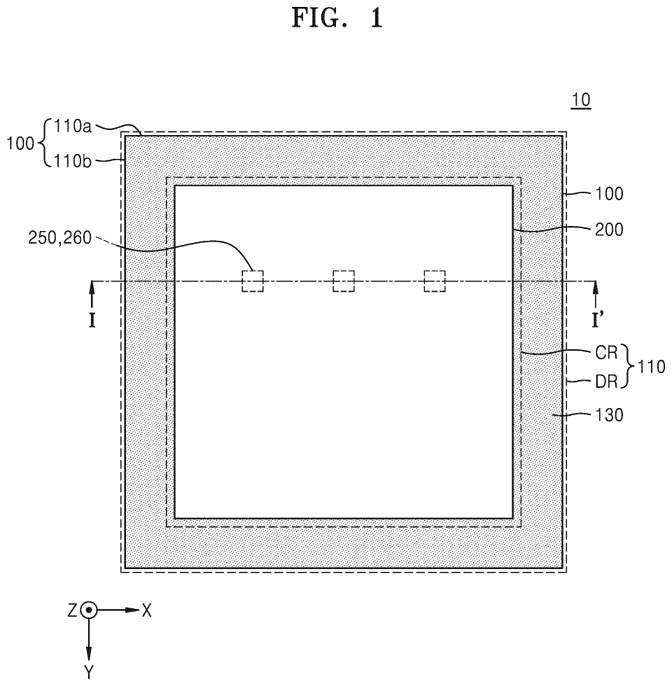

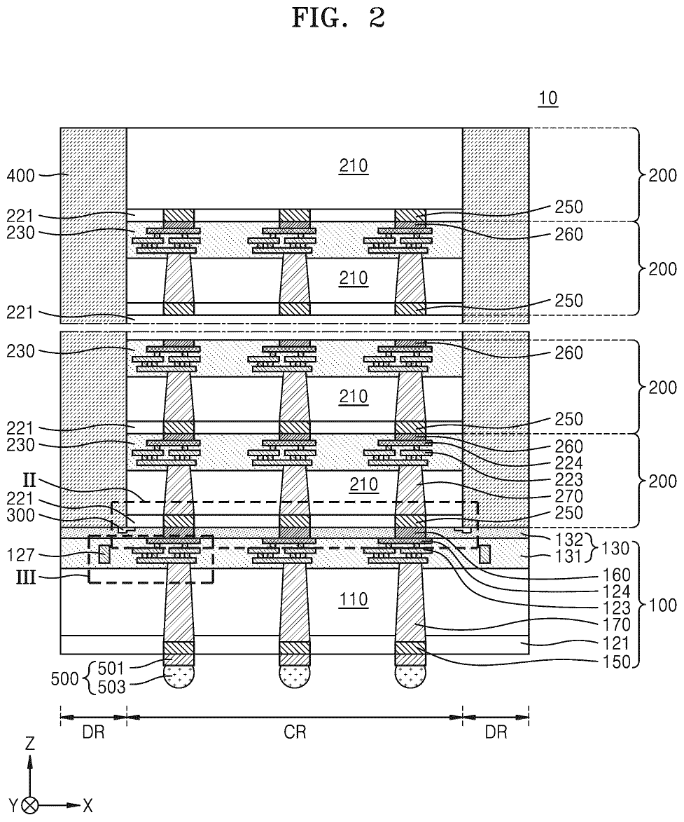

FIG. 1 is a plan view illustrating a semiconductor package 10 according to embodiments. FIG. 2 is a cross-sectional view taken along line I-I′ of FIG. 1, according to embodiments.

Referring to FIGS. 1 and 2, the semiconductor package 10 may include a memory package such as a high bandwidth memory (HBM) package. The semiconductor package 10 may include a chip stack package. The semiconductor package 10 may include a first semiconductor chip 100, second semiconductor chips 200, a molding layer 400, and a lower bump 500.

The first semiconductor chip 100 may be a lower semiconductor chip. The first semiconductor chip 100 may be a logic chip or a buffer chip. The first semiconductor chip 100 may include a first semiconductor substrate 110, a first lower pad 150, a first lower insulating layer 121, a first wiring pattern 123, a first through via 170, a first upper insulating layer 130, and a first upper pad 160. The first horizontal direction (e.g., X direction) may be parallel to a lower surface of the first semiconductor substrate 110. The second horizontal direction (e.g., Y direction) may intersect the lower surface of the first semiconductor substrate 110. The second horizontal direction (e.g., Y direction) may be parallel to the lower surface of the first semiconductor substrate 110 and intersect the first horizontal direction (e.g., X direction). For example, the second horizontal direction (e.g., Y direction) may be perpendicular to the first horizontal direction (e.g., X direction). For example, the third direction (e.g., Z direction) may be perpendicular to the lower surface of the first semiconductor substrate 110. The third direction (e.g., Z direction) may be a vertical direction.

The first semiconductor chip 100 may have a thickness in a range from about 30 μm to about 80 μm. Because the thickness of the first semiconductor chip 100 is 80 μm or less, the semiconductor package 10 may be miniaturized. because the thickness of the first semiconductor chip 100 is 30 μm or greater, damage to the first semiconductor chip 100 may be prevented during a manufacturing process of the semiconductor package 10. The thickness T of the first semiconductor chip 100 may correspond to a gap between a lower surface and the upper surface of the first semiconductor chip 100.

The plurality of second semiconductor chips 200 may be provided on the first semiconductor chip 100. The plurality of second semiconductor chips 200 may be vertically stacked on the upper surface of the first semiconductor chip 100. In the present specification, unless otherwise specified, “vertically” may denote being parallel to the vertical direction (e.g., Z direction). The plurality of second semiconductor chips 200 may be upper semiconductor chips. The plurality of second semiconductor chips 200 may be the same semiconductor chips as each other. Each of the second semiconductor chips 200 may be a memory chip or memory core chip such as a DRAM chip. For example, each of the second semiconductor chips 200 may be a high bandwidth memory (HBM) chip. A storage capacity of each of the second semiconductor chips 200 may be the same as each other. The second semiconductor chips 200 may have the same size as each other. For example, each of the second semiconductor chips 200 may have substantially the same width as each other. Sidewalls of the second semiconductor chips 200 may be vertically aligned with each other. However, the thickness of the uppermost second semiconductor chip 200 may be greater than the thicknesses of the remaining second semiconductor chips 200. The thicknesses of the remaining second semiconductor chips 200 may be substantially the same as each other.

A width of a component may be measured in the first horizontal direction (e.g., X direction). A thickness of a component may be measured in the vertical direction (e.g., Z direction). The fact that the widths, thicknesses, sizes, and levels of certain components are the same as each other may denote the sameness of an error range that may occur during a process. The second semiconductor chips 200 may be a different type of semiconductor chip from the first semiconductor chip 100. The width of the first semiconductor chip 100 may be greater than the widths of the second semiconductor chips 200.

The number of the second semiconductor chips 200 may be variously changed without being limited to the illustration of FIG. 2. For example, the semiconductor package 10 may include a single second semiconductor chip 200 or four or more second semiconductor chips 200. For example, the semiconductor package 10 may include eight second semiconductor chips 200, twelve second semiconductor chips 200, or sixteen second semiconductor chips 200.

Hereinafter, the components of the first semiconductor chip 100 will be described.

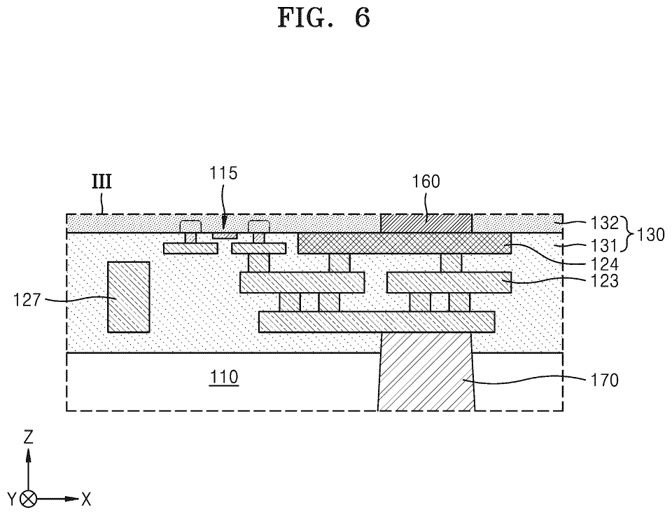

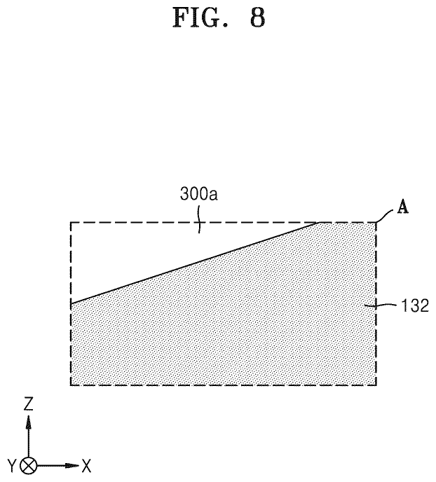

The first semiconductor substrate 110 may be a first substrate. The first semiconductor substrate 110 may have a chip region CR and a dummy region DR in a planar view. The chip region CR may correspond to the element region. The chip region CR may be a device region. The chip region CR of the first semiconductor substrate 110 may be a center region of the first semiconductor substrate 110. The dummy region DR of the first semiconductor substrate 110 may be an edge region of the first semiconductor substrate 110. The dummy region DR of the first semiconductor substrate 110 may surround the chip region CR in a planar view. For example, the dummy region DR of the first semiconductor substrate 110 may be provided between the chip region CR and an outer wall of the first semiconductor substrate 110. The first semiconductor substrate 110 may include a semiconductor material, for example, silicon, germanium, or silicon-germanium. The first semiconductor substrate 110 may include a crystalline semiconductor material. The first semiconductor chip 100 may include first integrated circuits 115 as shown in FIG. 6. The first integrated circuits 115 will be described in detail with reference to FIG. 8.

The outer wall of the first semiconductor chip 100 may include a first outer wall 110a, a second outer wall 110b, a third outer wall, and a fourth outer wall. The second outer wall 110b may be adjacent to the first outer wall 110a. The third outer wall may be opposite to the first outer wall 110a and adjacent to the second outer wall 110b. The fourth outer wall may be opposite to the second outer wall 110b and adjacent to the first outer wall 110a and the third outer wall.

The first semiconductor chip 100 may include a first lower pad 150 arranged on the lower surface of the first semiconductor substrate 110. The first lower insulating layer 121 is on the lower surface of the first semiconductor substrate 110 and may cover the first lower pad 150. The first lower insulating layer 121 may include a silicon-based insulating material. The silicon-based insulating material may include, for example, silicon oxide, silicon nitride, silicon oxynitride, and/or silicon carbide oxynitride. The first lower insulating layer 121 may include a plurality of stacked layers.

The first wiring pattern 123 may be provided within the first upper insulating layer 130. The first upper insulating layer 130 may include a plurality of layers. In some embodiments, the first upper insulating layer 130 may include a first insulating layer 131 and a second insulating layer 132. However, this is only for some embodiments, and the first upper insulating layer 130 may include three or more layers. The first wiring pattern 123, more specifically, may be provided within the first insulating layer 131. The first wiring pattern 123 may be electrically connected to at least one of the first integrated circuits 115 (see e.g., FIG. 6) and the first through-via 170.

The first wiring pattern 123 may include a first aluminum wiring pattern 124 on an upper portion thereof. The first aluminum wiring pattern 124 may include aluminum and a material different from the first wiring pattern 123. A component being electrically connected to a semiconductor chip may mean that the component is electrically connected to at least one of the through-via and the integrated circuits of the semiconductor chip. In the present specification, the meaning of being electrically connected/contacted includes direct connection/contact or indirect connection/contact through another conductive component.

The first lower pad 150 may be arranged on the lower surface of the first semiconductor chip 100. For example, the first lower pad 150 may be arranged on the lower surface of the first lower insulating layer 121. The vertical level of an upper surface of the first lower insulating layer 121 may be greater than or equal to the vertical level of an upper surface of the first lower pad 150. That is, the first lower pad 150 may be covered by the first lower insulating layer 121.

In example embodiments, the first lower insulating layer 121 may include an inorganic insulating material to which compressive stress is applied. In example embodiments, the first lower insulating layer 121 may be formed to have compressive stress by a plasma-enhanced chemical vapor deposition (PECVD) process. For example, the first lower insulating layer 121 may include at least one of an oxide and a nitride. For example, the first lower insulating layer 121 may include at least one of silicon oxide and silicon nitride. In order to adjust the compressive stress of the first lower insulating layer 121, the process conditions of the PECVD process for forming the first lower insulating layer 121 and/or the thickness of the first lower insulating layer 121 may be controlled.

The first lower pad 150 may be electrically connected to the first through-via 170. The upper surface of the first lower pad 150 may be in physical contact with the first through-via 170. The first lower pad 150 may include, for example, aluminum or copper. The lower surface of the first semiconductor chip 100 may include the lower surface of the first lower pad 150 and the lower surface of the first lower insulating layer 121.

The lower bump 500 may be arranged on the lower surface of the first semiconductor chip 100. For example, the lower bump 500 may be arranged on the lower surface of the first lower pad 150 and may be electrically connected to the first lower pad 150. Accordingly, the lower bump 500 may be electrically connected to the first semiconductor chip 100 and the second semiconductor chips 200 through the first lower pad 150. The lower bump 500 may include a conductive pillar 501 and a solder ball 503. The conductive pillar 501 may be provided between the first lower pad 150 and the solder ball 503 and may be electrically connected to the first lower pad 150 and the solder ball 503. The conductive pillar 501 may include a material different from that of the first lower pad 150 and the solder ball 503. For example, the conductive pillar 501 may include copper and/or a copper alloy. The solder ball 503 may include a solder material. The solder material may include tin (Sn), silver (Ag), zinc (Zn), and/or an alloy thereof.

The first semiconductor chip 100 may further include a guide ring 127. The guide ring 127 may be provided within the first upper insulating layer 130. The guide ring 127 may have a closed loop shape in a planar view. The guide ring 127 may be provided between the dummy region DR of the first semiconductor substrate 110 and the first wiring pattern 123 in a planar view. The guide ring 127 may protect the first wiring pattern 123 or the first integrated circuits 115 (see e.g., FIG. 6) from external contamination or external stress. The first guide ring 127 may include a metal material but is not limited thereto.

The first through-via 170 may be provided within the first semiconductor substrate 110 and may penetrate and/or pass through the first semiconductor substrate 110. The first through-via 170 may further penetrate at least a portion of the first lower insulating layer 121. The first through-via 170 may be electrically connected to the first wiring pattern 123. The first through-via 170 may be electrically connected to the first lower pad 150 and/or the first integrated circuits 115 (see e.g., FIG. 6) through the first wiring pattern 123. The first through-via 170 may include a metal, for example, copper, tungsten, titanium (Ti), titanium nitride (TiN), tantalum (Ta), and tantalum nitride (TaN).

The first upper insulating layer 130 may be disposed on an upper surface of the first semiconductor substrate 110. The upper surface of the first semiconductor substrate 110 may face the lower surface of a first insulating layer 131. The upper surface of the first semiconductor substrate 110 may be a backside surface. The first through via 170 may further be provided within the first upper insulating layer 130. The first upper insulating layer 130 may cover an upper sidewall of the first through via 170.

The first upper insulating layer 130 may include the first insulating layer 131 and a second insulating layer 132. The first insulating layer 131 may cover the upper surface of the first semiconductor substrate 110 on the upper surface of the first semiconductor substrate 110. The first insulating layer 131 may be a multilayer or a single layer. The first insulating layer 131 may include a silicon-based insulating material. The first wiring pattern 123 may be provided within the first insulating layer 131.

The second insulating layer 132 may be disposed on the first insulating layer 131. The second insulating layer 132 may include a different material from the first insulating layer 131. As an example, the second insulating layer 132 may include a silicon-based insulating material. As another example, the second insulating layer 132 may include an insulating polymer such as polyimide. An upper surface of the second insulating layer 132 may be the upper surface of the first semiconductor chip 100.

The first upper pad 160 may be disposed on the upper surface of the first semiconductor substrate 110. The first upper pad 160 may be provided above the first through-via 170 and may be electrically connected to the first through-via 170. In the present specification, the level of the component may denote a vertical level. The first upper pad 160 may be provided within the first upper insulating layer 130. More specifically, the first upper pad 160 may be provided within the second insulating layer 132. A portion of a lower surface and a side surface of the first upper pad 160 may be covered by the first upper insulating layer 130. An upper surface of the first upper pad 160 may not be covered by the first upper insulating layer 130. The first upper pad 160 may include a metal such as copper. The upper surface of the first semiconductor chip 100 may include an upper surface of the first upper insulating layer 130 and the upper surface of the first upper pad 160.

A change in temperature applied to the first semiconductor chip 100 may cause warpage of the first semiconductor chip 100. For example, while the first semiconductor chip 100 is heated from a first temperature to a second temperature, the first semiconductor chip 100 may be deformed upwardly convexly due to rapid thermal expansion of the metal wiring pattern of the first wiring pattern 123. In addition, the second semiconductor chips 200 may also be deformed upwardly convexly or downwardly concavely. In order to prevent cracks due to warpage of the first semiconductor chip 100 or the second semiconductor chips 200, the first semiconductor chip 100 may include a trench region 300. The trench region 300 may be arranged within the second insulating layer 132. In FIG. 2, it is depicted that the trench region 300 is positioned only within the second insulating layer 132, but if a depth of the trench region 300 increases, the trench region 300 may be positioned within not only the second insulating layer 132 but also the first insulating layer 131. At least a portion of the trench region 300 may overlap the second semiconductor chip 200. The remaining portion of the trench region 300 may overlap the molding layer 400. In some embodiments, the trench region may overlap an entirety or a portion of a periphery of the second semiconductor chip. From a planar view, the trench region 300 may be divided into a first region and a second region. In some embodiments, a region of the trench region 300 that overlaps with the second semiconductor chip 200 may be referred to as the first region. In some embodiments, a region of the trench region 300 that does not overlap the second semiconductor chip 200 may be referred to as the second region. The second region may overlap the molding layer 400. The first region and the second region may have different vertical levels. In some embodiments, when the vertical levels of each of the first region and the second region are different, the trench region 300 may have a step-like structure. That is, the trench region 300 including the first region and the second region may be formed with a double step difference.

In the drawings, the trench region 300 and the molding layer 400 are expressed to be distinguished, but the trench region 300 and the molding layer 400 may be filled with the same material. In some embodiments, the trench region 300 and the molding layer 400 may be filled with resin, epoxy molding compound (EMC), or any combination thereof. In some embodiments, only the first region overlapping with the second semiconductor chip 200 may be filled with resin. In some embodiments, the second region not overlapping with the second semiconductor chip 200 may be filled with EMC. In some embodiments, both the first region and the second region may be filled with the same material, and the same material may denote a mixture of resin and EMC.

The bonding strength may be improved by filling a gap of an edge or corner of an area where the first semiconductor chip 100 and the second semiconductor chip 200 are in contact with each other while filling the trench region 300 with resin or EMC.

By forming the trench region 300, when stacking a plurality of second semiconductor chips 200 on the upper surface of the first semiconductor chip 100, which may be a core chip, a direct impact between the first upper insulating layer 130 and the second semiconductor chip 200 may be alleviated, thereby improving one or more defects caused by cracks.

The molding layer 400 may cover the first upper insulating layer 130. Unlike the drawings, the upper surface of the first semiconductor substrate 110 may be a front surface, and a backside surface of the first semiconductor substrate 110 may be a front surface.

In this circumstance, the first integrated circuits 115 and the first wiring pattern 123 may be arranged on the backside surface of the first semiconductor substrate 110. Hereinafter, components of the second semiconductor chip 200 will be described.

As shown in FIG. 2, the second semiconductor chips 200 may be provided on the first semiconductor chip 100.

For example, the second semiconductor chips 200 may be arranged on the chip region CR of the first semiconductor substrate 110. Each of the second semiconductor chips 200 may include a second semiconductor substrate 210, a second integrated circuit, a second lower insulating layer 221, a second lower pad 250, a second wiring pattern 223, a second through-via 270, a second upper pad 260, and a second upper insulating layer 230. Unless otherwise stated, the material and electrical connection relationships of the second semiconductor substrate 210, the second integrated circuit, the second lower insulating layer 221, the second lower pad 250, the second wiring pattern 223, and the second through-via 270 may be substantially the same as the material and electrical connection relationships of the first semiconductor substrate 110, the first integrated circuits 115, the first lower insulating layer 121, the first lower pad 150, the first wiring pattern 123, and the first through-via 170, respectively. The second semiconductor substrate 210 may be a second substrate.

The second integrated circuits may be provided on a lower surface of the second semiconductor substrate 210. The lower surface of the second semiconductor substrate 210 may be a front surface. The second integrated circuits may be a different type of circuit from the first integrated circuits 115 (see e.g., FIG. 6). The second integrated circuits may be memory circuits. The second semiconductor substrate 210 may include a semiconductor material. The second lower insulating layer 221 may be provided on the lower surface of the second semiconductor substrate 210 and may cover the second integrated circuit.

The second lower insulating layer 221 may include multiple layers so as to be multilayer. The second lower insulating layer 221 may include a silicon-based insulating material. More specifically, the second lower insulating layer 221 may include an inorganic insulating material to which compressive stress is applied. In example embodiments, the second lower insulating layer 221 may be formed to have compressive stress by a plasma-enhanced chemical vapor deposition (PECVD) process. For example, the second lower insulating layer 221 may include at least one of an oxide and a nitride. For example, the second lower insulating layer 221 may include at least one of silicon oxide and silicon nitride. In order to control the compressive stress of the second lower insulating layer 221, process conditions of the PECVD process for forming the second lower insulating layer 221 and/or a thickness of the second lower insulating layer 221 may be controlled. The second lower pad 250 may be provided on a lower surface of the second semiconductor chip 200.

For example, the second lower pad 250 may be arranged on the lower surface of the second lower insulating layer 221. The lower surface of the second semiconductor chip 200 may include the lower surface of the second lower pad 250 and the lower surface of the second lower insulating layer 221. The second lower pad 250 may include, for example, copper. The second through-via 270 may be provided in the second semiconductor substrate 210 and may penetrate the second semiconductor substrate 210.

The second through-via 270 may be electrically connected to the second wiring pattern 223. The second through-via 270 may include a metal. Accordingly, the second lower pad 250 and the second wiring pattern 223 may be electrically connected through the second through via 270. The second upper insulating layer 230 may be disposed on an upper surface of the second semiconductor substrate 210.

The upper surface of the second semiconductor substrate 210 may be a backside surface. The second upper insulating layer 230 may include multiple layers so as to be multilayer. For example, the second upper insulating layer 230 may include a silicon-based insulating material. The second wiring pattern 223 may be provided within the second upper insulating layer 230. The second wiring pattern 223 may include a metal. The second wiring pattern 223 may include a second aluminum wiring pattern 224 thereon. The second aluminum wiring pattern 224 may include aluminum and a material different from the second wiring pattern 223. The second upper pad 260 may be electrically connected to the second integrated circuit and/or the second through-via 270 through the second wiring pattern 223. The second upper pad 260 may be arranged within the second upper insulating layer 230. An upper surface of the second upper pad 260 may not be covered by the second upper insulating layer 230. The second upper pad 260 may include, for example, a metal such as copper.

A change in temperature applied to the second semiconductor chips 200 may cause warpage of the second semiconductor chips 200. For example, while the second semiconductor chips 200 are heated from a first temperature to a second temperature, the second semiconductor chips 200 may be deformed to be upwardly convex or downwardly concave due to rapid thermal expansion of the metal wiring pattern of the second wiring pattern 223. In order to prevent cracks caused by such warpage, a trench region 300 may be arranged, and the description of trench region 300 is the same as described herein and is therefore omitted. The uppermost second semiconductor chip 200 may include the second semiconductor substrate 210, the second integrated circuit, the second lower insulating layer 221, and the second lower pad 250, but may not include the second through via 270, the second upper pad 260, the second wiring pattern 223, and the second upper insulating layer 230.

A thickness of the second semiconductor substrate 210 of the uppermost second semiconductor chip 200 may be greater than a thickness of the second semiconductor substrate 210 of each of the other second semiconductor chips 200. The uppermost second semiconductor chip 200 may be referred to as a third semiconductor chip. The molding layer 400 may be disposed on the upper surface of the first semiconductor chip 100 to cover one or more sidewalls of the second semiconductor chips 200. The molding layer may cover at least a portion of the second semiconductor chip(s).

The upper surface of the molding layer 400 may expose the upper surface of the uppermost second semiconductor chip 200. For example, the upper surface of the molding layer 400 may be provided at substantially the same level as the upper surface of the uppermost second semiconductor chip 200. Alternatively, the molding layer 400 may further cover the upper surface of the uppermost second semiconductor chip 200. The molding layer 400 may include an insulating polymer such as an EMC. The lowermost second semiconductor chip 200 may be directly bonded to the first semiconductor chip 100.

Each of the first semiconductor chip 100 and the second semiconductor chips 200 included in the semiconductor package 10 may be directly bonded. The direct bonding may be formed by a hybrid bonding process. The second lower pad 250 of the lowermost second semiconductor chip 200 may be directly bonded to the first upper pad 160. For example, the second lower pad 250 of the second lower semiconductor chip 200 is directly arranged on the first upper pad 160 and may be in direct physical contact with the first upper pad 160. The second lower pad 250 of the lowermost second semiconductor chip 200 may include the same metal (e.g., copper) as the first upper pad 160. An interface between the second lower pad 250 and the first upper pad 160 of the lowermost second semiconductor chip 200 may not be distinct, but is not limited thereto. The second lower insulating layer 221 of the lowermost second semiconductor chip 200 may be directly bonded to the first upper insulating layer 130.

For example, a chemical bond may be formed between the second lower insulating layer 221 and the first upper insulating layer 130 of the lowermost second semiconductor chip 200. In some embodiments, a bump and an insulating film surrounding the bump, which are arranged between the first semiconductor chip 100 and the second semiconductor chips 200 used in the circumstance of thermal compression bonding (TCB), may be omitted. By direct bonding, the thickness of the semiconductor package in the vertical direction may be relatively reduced. By direct bonding, the second lower insulating layer 221 of the lowermost second semiconductor chip 200 may be firmly bonded to the first upper insulating layer 130. The second lower insulating layer 221 of the lowermost second semiconductor chip 200 may include the same insulating material as the first upper insulating layer 130 but is not limited thereto. For example, an interface between the second lower insulating layer 221 of the lowermost second semiconductor chip 200 and the first upper insulating layer 130 may not be distinguished. The second semiconductor chips 200 may be directly bonded to each other.

For example, the second upper pad 260 and the second lower pad 250 facing each other may directly contact each other and may be directly bonded to each other. An interface between the second upper pad 260 and the second lower pad 250 directly bonded to each other may not be distinguished. The interface between the second upper pad 260 and the second lower pad 250 directly bonded to each other may be a virtual interface. The second lower pad 250 may include the same metal (e.g., copper) as the second upper pad 260 directly bonded thereto. The second lower insulating layer 221 may be directly bonded to the second upper insulating layer 230, and the second lower insulating layer 221 and second upper insulating layer 230 may face each other.

For example, the second lower insulating layer 221 may be in direct contact with the second upper insulating layer 230, and they may face each other. A chemical bond may be formed between the second lower insulating layer 221 and the second upper insulating layer 230 that are directly bonded to each other. Accordingly, a strong bond may be formed between the second lower insulating layer 221 and the second upper insulating layer 230 that are directly bonded to each other. The second lower insulating layer 221 may include the same material as the second upper insulating layer 230 that is directly bonded thereto, but is not so limited. For example, an interface between the second lower insulating layer 221 and the second upper insulating layer 230 that are directly bonded to each other may not be distinguished.

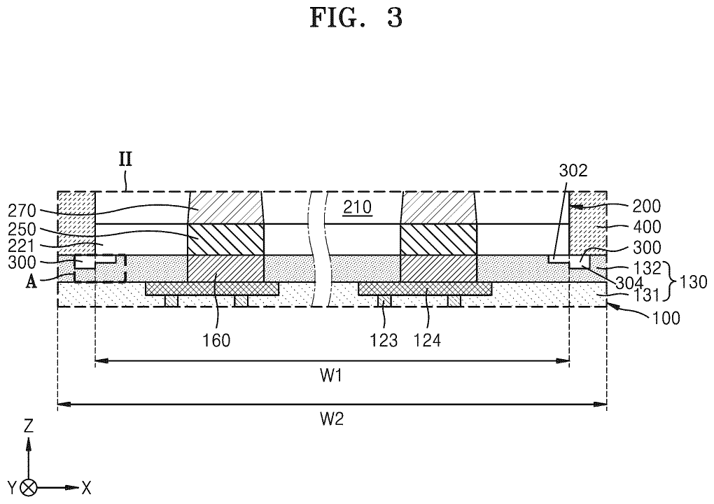

FIG. 3 is a diagram showing an enlarged view of a region II of FIG. 2, according to embodiments. FIG. 3 is referred to together with FIGS. 1 and 2.

The trench region 300 may be arranged at both ends based on the center of the second semiconductor chip 200. In the drawing of FIG. 3, it is depicted that the two trench regions 300 are arranged within the second insulating layer 132, but when viewed from above, there may be two or more trench regions 300 arranged within the second insulating layer 132. In some embodiments, four trench regions 300 may be arranged at each vertex of the second semiconductor chip 200. In some embodiments, the trench regions 300 may be divided into a first region and a second region as described herein. As shown in FIG. 3, portion 302 of the trench region 300 may be considered a first portion or as also referred to herein, a first region. Portion 304 of the trench region 300 may be considered a second portion or as also referred to herein, a second region. The first portion may be positioned laterally inside the periphery of the second semiconductor chip, and the second portion may be positioned laterally outside the periphery of the second semiconductor chip. The first portion and second portion of the trench region in combination may form a stepped structure or stepped shape. Portion 302, a first portion, may have a first depth that is less than a second depth of portion 304, a second portion. The first portion, portion 302, may have an inner edge in a horizontal direction (e.g., X) and the second portion, portion 304, may have an outer edge in the horizontal direction (e.g., X). As shown, the depth of the trench region 300 may change from the inner edge to the outer edge. The trench region may have a variable depth that increases moving laterally from an inner edge of the trench region toward an outer edge of the trench region.

A width of both ends of the first region may be defined as W1. A width of both ends of the second region may be defined as W2. In some embodiments, W1 may correspond to the longest width in the horizontal direction of the first region. In addition, W1 may correspond to a width in the horizontal direction of the second semiconductor chip 200. In some embodiments, W2 may correspond to the longest width in the horizontal direction of the second region. In FIG. 3, the longest width in the first horizontal direction (e.g., X) of the first region is illustrated as W1, but the longest width in the second horizontal direction (e.g., Y) orthogonal to the first horizontal direction (e.g., X) may also be defined as W1.

In addition, the longest width in the first horizontal direction (e.g., X) of the second region is illustrated as W2, but the longest width in the second horizontal direction (e.g., Y) orthogonal to the first horizontal direction (e.g., X) may also be defined as W2. It does not mean that there is the trench region 300 for all regions within the widths of W1 and W2, and the trench region 300 may not be formed continuously.

That is, W1 and W2 may be calculated as a length connecting the outermost points of each region. The trench region 300 may not be formed for some regions of the lower surface of the second semiconductor chip 200. In some embodiments, in the circumstance of FIG. 3, the second insulating layer 132 may physically contact the lower surface of the second semiconductor chip 200 without forming the trench region 300. The longest width of the first region, W1, may be less than the longest width of the second region, W2.

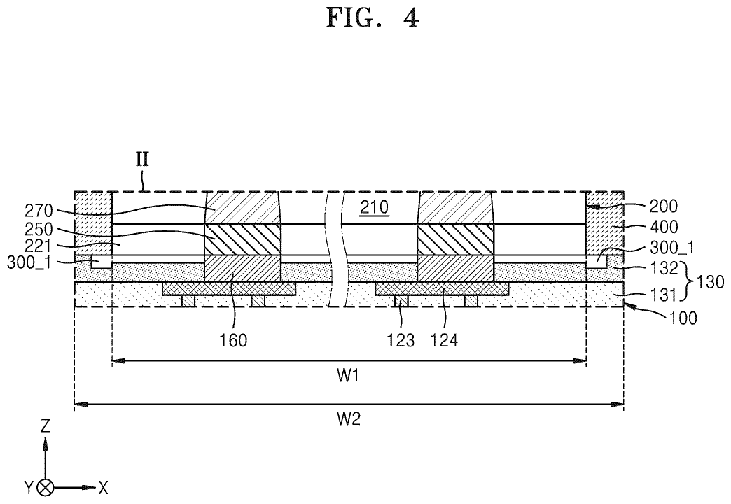

FIG. 4 is a diagram showing an enlarged view of the region II of FIG. 2, according to embodiments. FIG. 4 will be described with reference to FIGS. 1 to 3, mainly on differences from FIG. 3.

From a planar view, trench regions 300_1 may be connected to each other continuously. The trench regions 300_1 may have first and second regions with different vertical levels as in FIG. 3, but the first region among the trench regions 300_1 of FIG. 4 may be connected to each other continuously. In some embodiments, the trench region 300_1 may be formed along an outer surface of the second semiconductor chip 200 among regions where the second insulating layer 132 contacts the second semiconductor chip 200. In FIG. 4, from a planar view, it is depicted that the trench region 300_1 is formed by completely removing an upper surface of the second insulating layer 132, and the upper surface of the second insulating layer 132 is not in contact with the lower surface of the second semiconductor chip 200. However, when viewed from above, the central region among regions of the second insulating layer 132 where the trench region 300_1 is not formed may physically contact the second semiconductor chip 200.

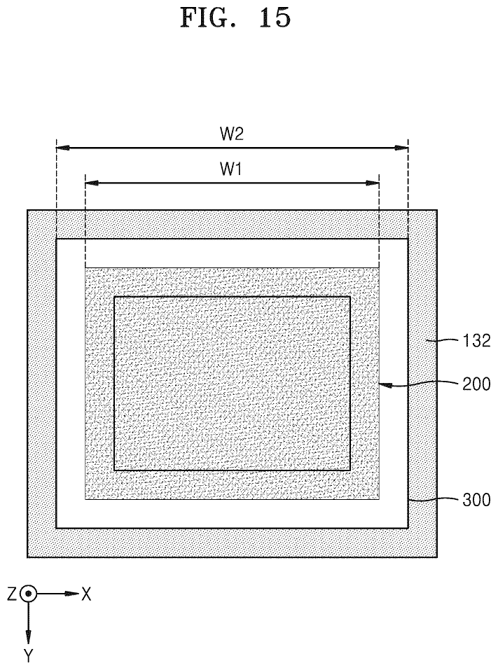

This will be described in detail with reference to FIG. 15. In the circumstance of the trench region 300_1 of FIG. 4, the longest width W1 of the first region may be less than the longest width W2 of the second region.

The trench region 300_1 is formed in succession, and even in the circumstance of the trench region 300_1, only the first region may overlap the second semiconductor chip 200. In addition, even in the circumstance of the trench region 300_1, the second region that does not overlap the second semiconductor chip 200 may overlap the molding layer 400.

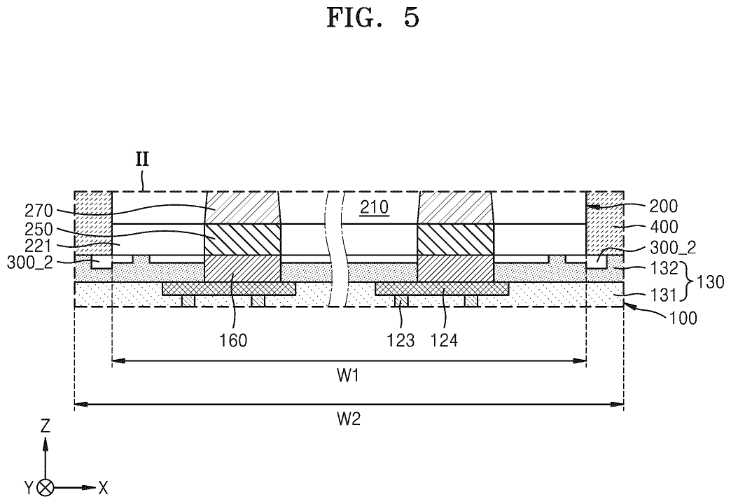

FIG. 5 is a diagram showing an enlarged view of the region II of FIG. 2, according to embodiments. FIG. 5 is referred to together with FIGS. 1 to 4, and mainly describes the differences from FIG. 4.

From a planar view, trench regions 300_2 may be arranged spaced apart from each other (e.g., discontinuous in a plane of an insulating layer).

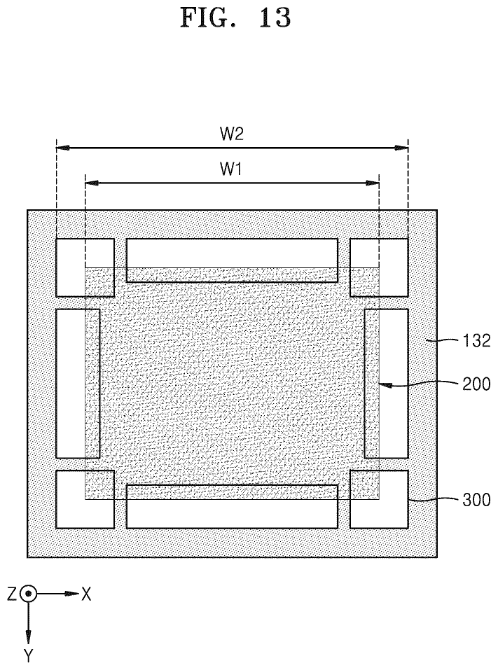

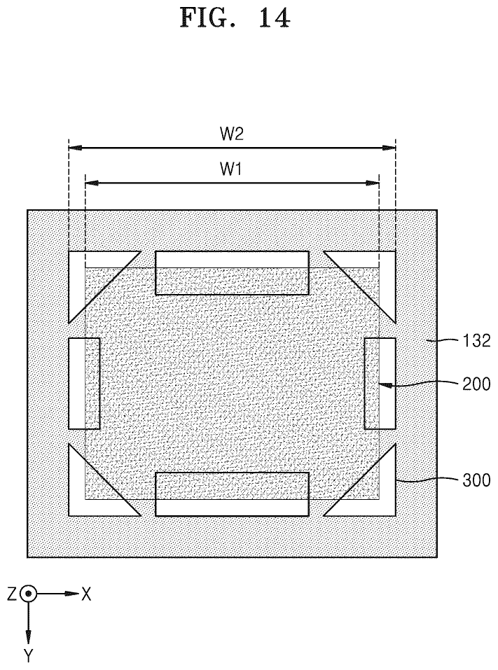

In some embodiments, the trench regions 300_2 may be arranged at or adjacent each corner of the second semiconductor chip 200 or at each vertex or edge of the second semiconductor chip 200. In the description of FIG. 5 herein, a corner may denote a corner of the second semiconductor chip 200, and a vertex may denote a vertex of the second semiconductor chip 200. The trench regions 300_2 arranged at the corner may not be continuous with the trench regions 300_2 arranged at the vertex. The trench regions 300_2 arranged at the corner may not be continuous with the trench regions 300_2 arranged at the corner. At both ends of the trench region 300_2 arranged at the corner, the trench region 300_2 arranged at the vertex may be arranged. The second insulating layer 132 may be arranged between the trench region 300_2 arranged at the corner and the trench region 300_2 arranged at the vertex. This is described in detail with reference to FIGS. 13 and 14. In the circumstance of the trench region 300_2 of FIG. 5, the longest width W1 of the first region may be less than the longest width W2 of the second region.

In addition, the trench region 300_2 formed at the corner may correspond to the first region. That is, the trench region 300_2 formed at the corner is illustrated as being formed at the center of the lower surface of the second semiconductor chip 200 in FIG. 5. A depth of the trench region 300_2 formed at the corner in the vertical direction may be less than a depth of the second region in the vertical direction.

The depth of the trench region 300_2 formed at the corner in the vertical direction may be the same as the depth of the first region in the vertical direction. That is, the first region among the trench region 300_2 formed at the corner and the trench region 300_2 formed at the vertex may be formed by the same process. The trench region 300_2 formed at the corner may completely overlap the second semiconductor chip 200 from a planar view. However, when looking at FIG. 13 and FIG. 14 together, they may not completely overlap when viewed from above. In the circumstance of the trench region 300_2 formed at the vertex, the trench region 300_2 may overlap the second semiconductor chip 200 only for the first region.

Additionally, in the circumstance of the trench region 300_1, the second region that does not overlap the second semiconductor chip 200 may overlap the molding layer 400.

FIG. 6 is a diagram showing an enlarged view of a region III of FIG. 2, according to embodiments.

Referring to FIG. 6, the first integrated circuits 115 may be arranged on an upper portion of the chip region CR of the first semiconductor substrate 110.

A lower surface of the first semiconductor substrate 110 may be a frontside surface. The first integrated circuits 115 may not be provided on the dummy region DR of the first semiconductor substrate 110. The first integrated circuits 115 may include transistors. The first integrated circuits 115 may include logic circuits. The first insulating layer 131 may be provided on the upper portion of the first semiconductor substrate 110 and may cover the first integrated circuits 115.

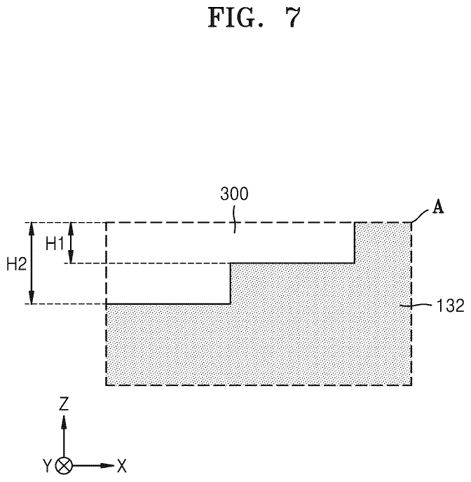

FIG. 7 is a diagram showing an enlarged view of a region A of FIG. 3, according to embodiments.

Referring to FIG. 7, the trench region 300 may be arranged within the second insulating layer 132.

The trench region 300 may be divided into a first region and a second region. In some embodiments, a length in the vertical direction (e.g., Z direction) of the first region is defined as H1. In some embodiments, the length in the vertical direction (e.g., Z direction) of the second region is defined as H2. A length H2 in the vertical direction (e.g., Z direction) of the second region among the trench region 300 may be greater than the length H1 in the vertical direction (e.g., Z direction) of the first region. In some embodiments, the length H2 in the vertical direction (e.g., Z direction) of the second region among the trench region 300 may be less than 1 μm.

In some embodiments, the length H1 in the vertical direction (e.g., Z direction) of the first region among the trench region 300 may be less than or equal to half of H2. That is, H1 may be less than half the length of H2. The first region and the second region may have distinct steps, so they may be a distinguishable step-shape. That is, the trench region 300 including the first region and the second region may have no slope.

FIGS. 8 to 10 are diagrams showing enlarged views of the region A of FIG. 3, according to embodiments.

Referring to FIG. 8 together with FIG. 1 and FIG. 2, a trench region 300a may be arranged within the second insulating layer 132.

From a planar view, in some embodiments, the trench region 300a may have a vertical (e.g., Z-direction) length that increases toward an edge of the first semiconductor chip 100. The trench region 300a may have a triangular shape with a constant slope. Although the trench region 300a is not divided into the first region and the second region as described herein, the depth of the portion corresponding to the second region in the vertical direction (e.g., Z-direction) may be greater than the depth of the portion corresponding to the first region in the vertical direction (e.g., Z-direction).

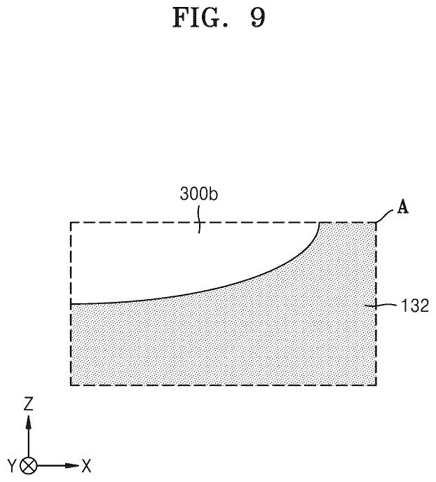

The trench region 300a is illustrated only for the A region, but in the circumstance of the trench region 300a being located on the opposite side based on the center of the second semiconductor chip 200, the tilted angle may be opposite. Referring to FIG. 9 together with FIG. 1 and FIG. 2, a trench region 300b may be arranged within the second insulating layer 132.

In a planar view, the trench region 300b may have a vertical length that increases toward the edge of the first semiconductor chip 100. In some embodiments, the trench region 300b may have a gentle or gradual curvature. In some embodiments, the trench region 300b may have a convex shape that protrudes toward the upper surface of the first semiconductor chip 100. That is, the second insulating layer 132 in which the trench region 300b is formed may have a concave shape that is concave toward the lower surface of the second semiconductor chip 200. The trench region 300b shown in FIG. 9 is not divided into a first region and a second region as described herein, but a depth in the vertical direction (e.g., Z direction) of the portion corresponding to the second region may be greater than a depth in the vertical direction (e.g., Z direction) of the portion corresponding to the first region.

The trench region 300b is illustrated only for the A region, but in the circumstance of the trench region 300b being located on the opposite side from the center of the second semiconductor chip 200, the angle at which the gentle (or gradual) curvature is formed may be opposite.

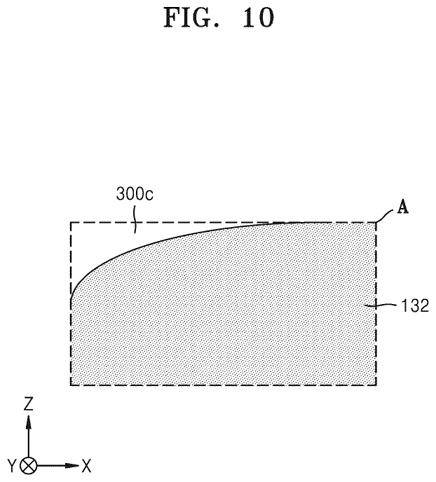

Referring to FIG. 10 together with FIG. 1 and FIG. 2, a trench region 300c may be arranged within the second insulating layer 132.

From a planar view, the trench region 300c may have a vertical length that increases as it goes toward the edge of the first semiconductor chip 100. In some embodiments, the trench region 300c may have a gentle or gradual curvature. In some embodiments, the trench region 300c may have a concave shape toward the upper surface of the first semiconductor chip 100. That is, the second insulating layer 132 in which the trench region 300c is formed may have a convex shape protruding toward the lower surface of the second semiconductor chip 200. The trench region 300c shown in FIG. 10 is not divided into the first region and the second region as described herein, but a depth in the vertical direction (e.g., Z direction) of the portion corresponding to the second region may be greater than a depth in the vertical direction (e.g., Z direction) of the portion corresponding to the first region.

The trench region 300c is illustrated only for the A region, but in the circumstance of the trench region 300c being located on the opposite side based on the center of the second semiconductor chip 200, an angle at which the gentle or gradual curvature is formed may be opposite.

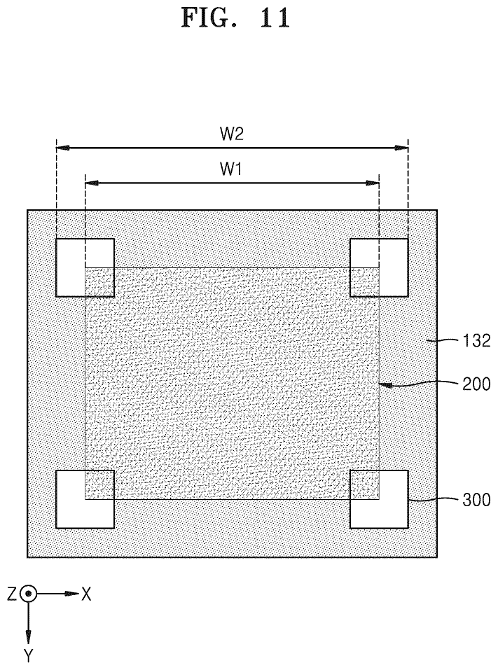

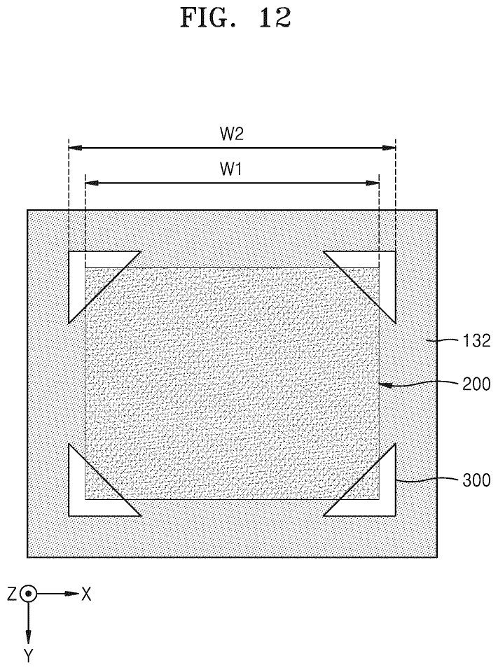

FIG. 11 is a plan view illustrating a trench region included in a semiconductor package according to embodiments. FIGS. 12 to 15 are plan views illustrating a trench region according to embodiments. In the description of FIGS. 11 to 15, a simply described corner denotes a corner of the second semiconductor chip 200, and a simply described vertex denotes a vertex of the second semiconductor chip 200. FIG. 11 is referred to together with FIGS. 1 and 2.

When viewed from above, the trench regions 300 may be arranged within the second insulating layer 132. A trench region collection may have multiple trench regions such as shown in FIG. 11. For example, there may be four trench regions 300. In some embodiments, the trench regions 300 may be arranged at each vertex of the second semiconductor chip 200 and may be spaced apart from each other. At least a portion of the trench regions 300 may overlap the second semiconductor chip 200. In some embodiments, a region of the trench region 300 that overlaps with the second semiconductor chip 200 may be a first region. In some embodiments, the remaining area of the trench region 300 that does not overlap the second semiconductor chip 200 may be a second region. The description of the longest widths W1 and W2 of each region of the trench region 300 are omitted as each are described above. The trench region 300 may have a square shape when viewed from above.

In the drawing, the trench region 300 is depicted as a square shape with each side having the same length, but is not limited thereto, and may have a rectangular shape with each side having different lengths. Each vertex of the second semiconductor chip 200 is depicted as corresponding to the horizontal center of the trench region 300, but the vertex of the second semiconductor chip 200 may not necessarily correspond to the center of the trench region 300. In FIG. 11, depths of the first region and the second region are depicted as being constant, but the depths of the first region and the second region may be different from each other as depicted in FIG. 7. In addition, the trench region 300 may be formed not only as a step shape with double steps as depicted in FIG. 7, but also as a triangle, concave shape, and convex shape as depicted in FIGS. 8 to 10. This may also be applied to the trench region 300 depicted in FIGS. 12 to 15 in the same manner. FIG. 11 may correspond to FIG. 3 from a planar view (e.g., a plane of an insulating layer). FIG. 12 is referred to together with FIGS. 1 and 2.

When viewed from above, the trench region 300 may be arranged within the second insulating layer 132. A trench region collection may have multiple trench regions such as shown in FIG. 12. For example, there may be four trench regions 300. In some embodiments, the trench regions 300 may be arranged at each vertex of the second semiconductor chip 200 and may be spaced apart from each other. At least a portion of the trench regions 300 may overlap the second semiconductor chip 200. In some embodiments, a region of the trench region 300 that overlaps with the second semiconductor chip 200 may be a first region. In some embodiments, the remaining region of the trench region 300 that does not overlap the second semiconductor chip 200 may be a second region. The trench regions 300 may have a right triangle shape (e.g., right-angled triangle) when viewed from above.

More specifically, the trench regions 300 may have a right triangle shape in which at least a portion of the hypotenuse overlaps with the second semiconductor chip 200. In the drawing, the trench region 300 is depicted as an isosceles triangle in which each side except the hypotenuse is the same length, but it is not limited thereto, and may be a right triangle in which each side has a different length. In addition, at least some of the hypotenuses may overlap the second semiconductor chip 200, but the angles of the sides that do not overlap may be triangles that are not right angled. In some embodiments, the trench region 300 may be an obtuse triangle or an acute triangle. FIG. 12 may correspond to FIG. 3 in a planar view. FIG. 13 is referred to together with FIG. 1 and FIG. 2.

When viewed from above, the trench region 300 may be arranged within the second insulating layer 132. A trench region collection may have multiple trench regions such as shown in FIG. 13. For example, there may be eight trench regions 300. In some embodiments, the trench region 300 may be arranged at each vertex and each corner of the second semiconductor chip 200 and may be spaced apart from each other. At least a portion of the trench region 300 may overlap the second semiconductor chip 200. In some embodiments, a region of the trench region 300 that overlaps with the second semiconductor chip 200 may be a first region. In some embodiments, the remaining region of the trench region 300 that does not overlap the second semiconductor chip 200 may be a second region. The trench region 300 may have a square shape when viewed from above.

In the drawing, the trench regions 300 located at the corner of the second semiconductor chip 200 is depicted as a square shape with each side having the same length, and the trench region 300 located at the corners of the second semiconductor chip 200 is depicted as a rectangular shape, but this is not limited thereto. In some embodiments, the one located at the corner of the second semiconductor chip 200 may be a rectangular shape with different lengths of each side. In some embodiments, the one located at the corner of the second semiconductor chip 200 may be a square shape with the same lengths of each side. Although each corner of the second semiconductor chip 200 is depicted as corresponding to the center of the trench region 300 in the horizontal direction, the corner of the second semiconductor chip 200 may not necessarily correspond to the center of the trench region 300. The trench region 300 located at the corner of the second semiconductor chip 200 and the trench region 300 located at the corner may be located separately from each other.

The second insulating layer 132 may be arranged between the trench region 300 arranged at the corner and the trench region 300 arranged at the vertex. FIG. 13 may correspond to FIG. 5 in a planar view. FIG. 14 is referred to together with FIG. 1 and FIG. 2.

When viewed from above, the trench region 300 may be arranged within the second insulating layer 132. A trench region collection may have multiple trench regions such as shown in FIG. 14. For example, there may be eight trench regions 300. In some embodiments, the trench regions 300 may be arranged at each vertex and each corner of the second semiconductor chip 200 and may be spaced apart from each other. At least a portion of the trench region 300 may overlap the second semiconductor chip 200. In some embodiments, a region of the trench region 300 that overlaps with the second semiconductor chip 200 may be a first region. In some embodiments, the remaining region of the trench region 300 that does not overlap the second semiconductor chip 200 may be a second region. When viewed from above, the trench region 300 may be in the shape of a right triangle or a square.

In the circumstance of a right triangle, more specifically, the trench region 300 may be in the shape of a right triangle in which at least a portion of the hypotenuse overlaps with the second semiconductor chip 200. In the drawing, the trench region 300 is depicted in the shape of a right triangle arranged at the vertex of the second semiconductor chip 200, and the trench region 300 is depicted in the shape of a rectangle arranged at the corner of the second semiconductor chip 200, but is not limited thereto. In some embodiments, the trench region 300 is depicted as an isosceles triangle in which each side except the hypotenuse is the same length, but it may be a right triangle in which each side has different lengths. In addition, at least some of the hypotenuses may overlap the second semiconductor chip 200, but angles of sides that do not overlap may be non-right angles in a triangle. In some embodiments, the trench region 300 may be an obtuse triangle or an acute triangle. The trench region 300 arranged at the vertex may have a rectangular shape in which each side has different lengths.

In some embodiments, the trench region 300 arranged at the corner of the second semiconductor chip 200 may be a square shape in which each side has the same length. Although it is depicted that each vertex of the second semiconductor chip 200 corresponds to the horizontal center of the trench region 300, the vertex of the second semiconductor chip 200 may not necessarily correspond to the center of the trench region 300. The trench region 300 arranged at the corner of the second semiconductor chip 200 and the trench region 300 arranged at the vertex may be arranged separately from each other.

The second insulating layer 132 may be arranged between the trench region 300 arranged at the corner and the trench region 300 arranged at the vertex. FIG. 14 may correspond to FIG. 5 from a planar view. FIG. 15 is referred to together with FIG. 1 and FIG. 2.

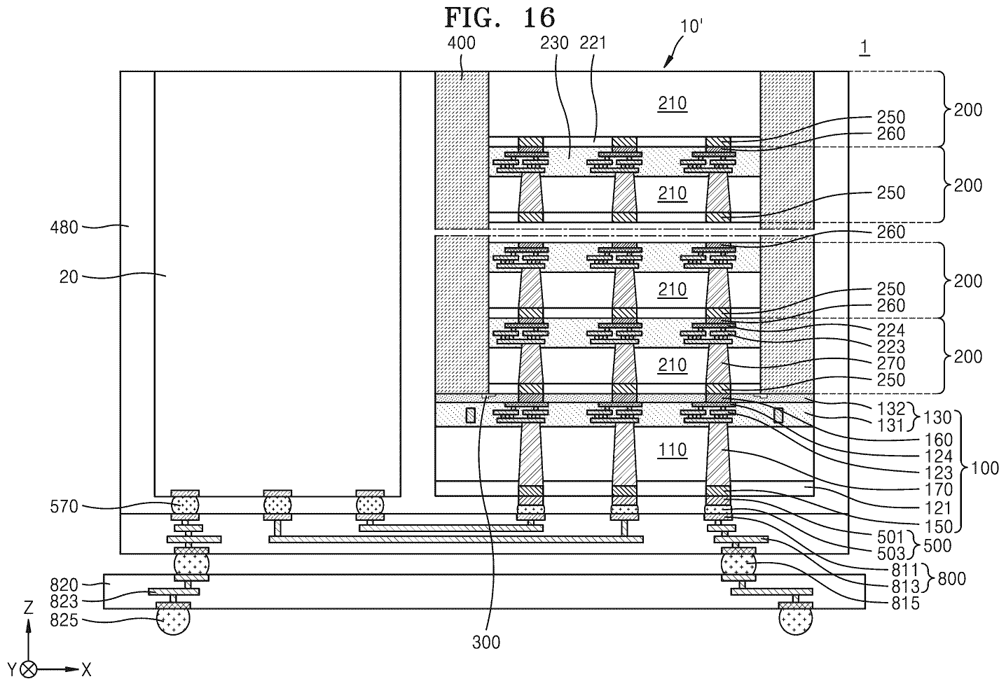

When viewed from above, the trench region 300 may be arranged within the second insulating layer 132. The trench region 300 may be formed as a continuous single configuration. When viewed from above, the second insulating layer 132 may be formed on both an outer surface and an inner surface of the trench region 300. That is, the trench region 300 may be arranged continuously (e.g., successively) along an outer surface of the second semiconductor chip 200. In some embodiments, the trench region 300 is formed along the outer surface of the second semiconductor chip 200 but has an outer surface that is further outward than the outer surface of the second semiconductor chip 200. In some embodiments, the trench region 300 is formed along the outer surface of the second semiconductor chip 200 but has an inner surface that is further inward than the outer surface of the second semiconductor chip 200. At least a portion of the trench region 300 may overlap the second semiconductor chip 200. In some embodiments, a region of the trench region 300 that overlaps with the second semiconductor chip 200 may be a first region. In some embodiments, the remaining region of the trench region 300 that does not overlap the second semiconductor chip 200 may be a second region. FIG. 15 may correspond to FIG. 4 in a planar view. FIG. 16 is a cross-sectional view illustrating a semiconductor package 1 according to embodiments.

Referring to FIG. 16, the semiconductor package 1 may include solder balls 825, a package substrate 820, interposer solder balls 815, an interposer substrate 800, a semiconductor device 20, and a chip stack package 10′.

For example, a printed circuit board may be used as the package substrate 820.

The package substrate 820 may include substrate wirings 823. The substrate wirings 823 may be provided within the package substrate 820. Being electrically connected to the package substrate 820 may denote being electrically connected to at least one of the substrate wirings 823. The substrate wirings 823 may include a metal such as copper, aluminum, tungsten, and/or titanium. The solder balls 825 may be provided on a lower surface of the package substrate 820 and may be electrically connected to the substrate wirings 823.

External electrical signals may be transmitted to the solder balls 825. The solder balls 825 may include a solder material. The interposer substrate 800 may be provided on the package substrate 820.

The interposer substrate 800 may include upper interposer pads 811 and interposer wirings 813. The upper interposer pads 811 may be arranged on an upper surface of the interposer substrate 800. The upper interposer pads 811 may include a metal. The interposer wirings 813 may be provided within the interposer substrate 800 and may be electrically connected to the upper interposer pads 811. Being electrically connected to the interposer substrate 800 may denote being electrically connected to at least one of the interposer wirings 813. The interposer wirings 813 may include a metal such as copper, aluminum, tungsten, and/or titanium. The interposer solder balls 815 may be disposed between the package substrate 820 and the interposer substrate 800 to electrically connect the package substrate 820 to the interposer substrate 800.

A pitch of the interposer solder balls 815 may be less than a pitch of the solder balls 825. The interposer solder balls 815 may include a solder material. The chip stack package 10′ may be disposed on an upper surface of the interposer substrate 800.

The semiconductor package 10 described in the depicted embodiment as described with reference to FIG. 2 may be used as the chip stack package 10′. For example, the chip stack package 10′ may include the first semiconductor chip 100, the second semiconductor chips 200, a molding layer 400, and the lower bumps 500. The lower bumps 500 may be arranged on the upper interposer pads 811 and electrically connected to the upper interposer pads 811. The lower bumps 500 may be between the interposer substrate and the first semiconductor chip.

For example, the lower bumps 500 may be bonded to upper surfaces of the corresponding upper interposer pads 811. A pitch of the lower bumps 500 may be less than a pitch of the interposer solder balls 815. A semiconductor device 20 may be provided on the interposer substrate 800 and may be spaced laterally from the chip stack package 10′.

The semiconductor device 20 may include a graphic processing unit (GPU) or a central processing unit (CPU). The semiconductor device 20 may be a semiconductor chip of a different type from the first semiconductor chip 100 and the second semiconductor chips 200. The semiconductor device 20 may perform a different function from the first semiconductor chip 100 and the second semiconductor chips 200. The semiconductor device 20 may include integrated circuits and chip pads. The integrated circuits may be provided within the semiconductor device 20. The chip pads may be provided on a lower surface of the semiconductor device 20 and may be electrically connected to the integrated circuits of the semiconductor device 20. Conductive bumps 570 may be disposed between the interposer substrate 800 and the semiconductor device 20.

For example, the conductive bumps 570 may be electrically connected to the chip pads of the semiconductor device 20 and the corresponding upper interposer pads 811. The conductive bumps 570 may include a solder material. A pitch of the conductive bumps 570 may be less than the pitch of the interposer solder balls 815. The semiconductor device 20 may be electrically connected to the chip stack package 10′ through the interposer substrate 800. The semiconductor device 20 may be electrically connected to the package substrate 820 and the solder balls 825 through the interposer substrate 800. A molding pattern 480 may be arranged on an upper surface of the interposer substrate 800 to cover sidewalls of the chip stack package 10′ and sidewalls of the semiconductor element 20.

For example, the molding pattern 480 may cover outer sidewalls of the first semiconductor chip 100 and outer sidewalls of the molding layer 400. The molding pattern 480 may include a polymer, such as an epoxy molding compound. The molding pattern 480 may have insulating properties. Unlike as illustrated, the semiconductor package 1 may include two or more chip stack packages 10′. In this circumstance, the semiconductor device 20 may be located between the chip stack packages 10′.

According to some aspects, there is provided a semiconductor package manufacturing method. The semiconductor manufacturing method may produce one or more semiconductor packages according to the technology described herein.

In some embodiments, the semiconductor package manufacturing method may include a step of providing one or more second semiconductor chips on a first semiconductor chip and a step of bonding the first semiconductor chip and a lowermost one of the one or more second semiconductor chips, wherein the first semiconductor chip may include: a first semiconductor substrate; a first upper insulating layer arranged on an upper surface of the first semiconductor substrate; a first upper pad arranged within the first upper insulating layer; a first lower pad arranged on a lower surface of the first semiconductor substrate; and a trench region which may be arranged within the first upper insulating layer.

In some embodiments, the trench region may have a first portion positioned laterally inside the periphery of the second semiconductor chip and a second portion positioned laterally outside the periphery of the second semiconductor chip, and the first portion of the trench region may have a first depth and the second portion of the trench region may have a second depth, wherein the first depth is less than the second depth.

In some embodiments, the trench region may have a variable depth that increases moving laterally from an inner edge of the trench region toward an outer edge of the trench region, and wherein the trench region is positioned to be laterally overlapping with the periphery of the second semiconductor chip.

In some embodiments, each of the one or more second semiconductor chips may include: a second semiconductor substrate; a second lower pad arranged on a lower surface of the second semiconductor substrate; and a second upper pad arranged on an upper portion of the second semiconductor substrate. In some embodiments, the bonding may include a hybrid bonding process.

In some embodiments, the method may further include providing a molding layer covering at least a portion of the one or more second semiconductor chips on the first semiconductor chip.

According to some aspects, there is provided a chip stack package, comprising: a first semiconductor chip having an insulating layer; and a second semiconductor chip positioned on the insulating layer of the first semiconductor chip and having a periphery, wherein the first semiconductor chip comprises a trench region in the insulating layer, the trench region having a first portion positioned laterally inside the periphery of the second semiconductor chip and a second portion positioned laterally outside the periphery of the second semiconductor chip, and wherein the first portion of the trench region has a first depth and the second portion of the trench region has a second depth, wherein the first depth is less than the second depth.

In some embodiments, the first portion and second portion of the trench region in combination form a stepped structure. In some embodiments, the trench region overlaps an entirety of the periphery of the second semiconductor chip. In some embodiments, the trench region overlaps a portion of the periphery of the second semiconductor chip. In some embodiments, the trench region is positioned adjacent a corner or edge of the second semiconductor chip. In some embodiments, the second semiconductor chip is a memory core chip.

According to some aspects, there is provided a chip stack package, comprising: a first semiconductor chip having an insulating layer; and a second semiconductor chip positioned on the insulating layer of the first semiconductor chip and having a periphery, wherein the first semiconductor chip comprises a trench region in the insulating layer, the trench region having a variable depth that increases moving laterally from an inner edge of the trench region toward an outer edge of the trench region, and wherein the trench region is positioned to be laterally overlapping with the periphery of the second semiconductor chip.

In some embodiments, the trench region has a stepped shape, concave shape, or convex shape moving laterally from the inner edge of the trench region toward the outer edge of the trench region. In some embodiments, the trench region is square or triangular in a plane of the insulating layer. In some embodiments, the trench region is continuous in a plane of the insulating layer. In some embodiments, the trench region is discontinuous in a plane of the insulating layer.

While the inventive concepts have been particularly shown and described with reference to embodiments thereof, it will be understood that various changes in form and details may be made therein without departing from the spirit and scope of the following claims.

What is claimed is:

1. A semiconductor package comprising:
a first semiconductor chip having a device region and a dummy region surrounding the device region in a planar view;
a second semiconductor chip on an upper surface of the device region of the first semiconductor chip; and
a molding layer covering at least a portion of the second semiconductor chip on the first semiconductor chip,
wherein the first semiconductor chip comprises:
a first semiconductor substrate;
a first lower pad arranged on a lower surface of the first semiconductor substrate;
a first upper insulating layer arranged on an upper portion of the first semiconductor substrate; and
a first upper pad and a trench region, each of the first upper pad and the trench region being arranged within the first upper insulating layer.

2. The semiconductor package of claim 1, wherein:
the first upper insulating layer includes a first insulating layer and a second insulating layer,
the first upper pad and the trench region are arranged within the second insulating layer of the first upper insulating layer, and
a width of the second semiconductor chip in a horizontal direction is less than a longest width of the trench region in the horizontal direction.

3. The semiconductor package of claim 1, wherein:
in a planar view, the trench region comprises a first region that overlaps the second semiconductor chip and a second region that does not overlap the second semiconductor chip, and
the trench region has a step-like structure in which vertical levels of the first region and the second region are different from each other.

4. The semiconductor package of claim 3, wherein a vertical length of the second region is 1 μm, and a vertical length of the first region is less than half the vertical length of the second region.

5. The semiconductor package of claim 1, wherein,
when viewed from above, the trench region is arranged at each vertex of the second semiconductor chip, each of the trench regions being spaced apart from each other.

6. The semiconductor package of claim 5, wherein, when viewed from above,
a shape of the trench region is a right-angled triangle shape in which at least part of the hypotenuse overlaps the second semiconductor chip.

7. The semiconductor package of claim 1, wherein,
when viewed from above, the trench region is arranged at each vertex and each corner of the second semiconductor chip, each of the trench regions being spaced apart from each other.

8. The semiconductor package of claim 7, wherein,
when viewed from above, a shape of the trench region arranged at each vertex of the second semiconductor chip among the trench regions is a right-angled triangle shape in which at least a portion of the hypotenuse overlaps the second semiconductor chip.

9. The semiconductor package of claim 1, wherein, when viewed from above, the trench region is arranged successively along an outer surface of the second semiconductor chip.

10. The semiconductor package of claim 1, wherein the second semiconductor chip includes:
a second semiconductor substrate;
a second lower pad arranged on a lower surface of the second semiconductor substrate; and
a second upper pad arranged on an upper portion of the second semiconductor substrate, and
wherein:
the first semiconductor chip and the second semiconductor chip at a lowermost portion are formed by a hybrid bonding process, and
the first upper pad and the second lower pad are in direct physical contact with each other.

11. A semiconductor package comprising:
a first semiconductor chip;
second semiconductor chips on an upper surface of the first semiconductor chip; and
a molding layer covering at least a portion of the second semiconductor chips on the first semiconductor chip,
wherein the first semiconductor chip includes:
a first semiconductor substrate,
a first upper insulating layer arranged on an upper surface of the first semiconductor substrate,
a first upper pad arranged within the first upper insulating layer,
a first lower pad arranged on a lower surface of the first semiconductor substrate, and
a trench region arranged within the first upper insulating layer;
wherein each of the second semiconductor chips includes:
a second semiconductor substrate,
a second lower pad arranged on a lower surface of the second semiconductor substrate, and
a second upper pad arranged on an upper portion of the second semiconductor substrate; and
wherein a width in a horizontal direction of each second semiconductor chip is less than a longest width in the horizontal direction of the trench region.

12. The semiconductor package of claim 11, wherein, in a planar view, the trench region is a triangular shape with a vertical length increasing toward an edge of the first semiconductor chip and having a constant slope.

13. The semiconductor package of claim 11, wherein,
in a planar view, the trench region has a gradual curvature with a vertical length that increases toward an edge of the first semiconductor chip and a convex shape protruding toward an upper surface of the first semiconductor chip.

14. The semiconductor package of claim 11, wherein:
in a planar view, the trench region has a gradual curvature with a vertical length that increases towards an edge of the first semiconductor chip and a concave shape toward an upper surface of the first semiconductor chip.

15. The semiconductor package of claim 11, wherein:
in a planar view, the trench region comprises a first region that overlaps each second semiconductor chip and a second region that does not overlap each second semiconductor chip, and
the trench region has a step-like structure in which vertical levels of the first region and the second region are different from each other.

16. The semiconductor package of claim 15, wherein a vertical length of the second region is 1 μm, and a vertical length of the first region is less than half the vertical length of the second region.

17. The semiconductor package of claim 11, further comprising:
an interposer substrate;
bumps between the interposer substrate and the first semiconductor chip; and
a semiconductor device disposed on an upper surface of the interposer substrate and spaced laterally from the first semiconductor chip,
wherein:
the first semiconductor chip is electrically connected to the semiconductor device through the interposer substrate,
the first upper insulating layer includes a first insulating layer and a second insulating layer, and
the first upper pad and the trench region are arranged within the second insulating layer of the first upper insulating layer.

18. The semiconductor package of claim 11, wherein:
the first semiconductor chip and a lowermost one of the second semiconductor chips are formed by a hybrid bonding process, the first upper pad and the second lower pad are in direct physical contact with each other,
the second semiconductor chips are formed by a hybrid bonding process, and
the second lower pad and the second upper pad closest to the second lower pad are in direct physical contact with each other.

19. A semiconductor package comprising:
a first semiconductor chip comprising:
a first semiconductor substrate,
a first upper insulating layer including a first insulating layer and a second insulating layer, the first upper insulating layer being disposed on an upper surface of the first semiconductor substrate,
a first upper pad disposed within the second insulating layer,
a trench region disposed within the second insulating layer;
second semiconductor chips on an upper surface of the first semiconductor chip, each of the second semiconductor chips including:
a second semiconductor substrate,
a second upper insulating layer disposed on an upper surface of the second semiconductor substrate,
a second lower insulating layer disposed on a lower surface of the second semiconductor substrate,
a second upper pad disposed within the second upper insulating layer, and
a second lower pad disposed within the second lower insulating layer; and
a molding layer covering at least one sidewall of the second semiconductor chips on the first semiconductor chip;
wherein, in a planar view, the trench region comprises a first region that overlaps the second semiconductor chips and a second region that does not overlap the second semiconductor chips, and
wherein the trench region has a step-like structure in which vertical levels of the first region and the second region are different from each other.

20. The semiconductor package of claim 19, further comprising:
a lower bump provided on a lower surface of the first semiconductor chip and electrically connected to the first lower pad;
wherein:
a vertical length of the second region is 1 μm;
a vertical length of the first region is less than half the vertical length of the second region;
the first semiconductor chip further comprises:
a first through-via passing through the first semiconductor substrate,
a first wiring pattern electrically connected to the first through-via and the first upper pad and disposed within the first insulating layer, and
a first lower pad disposed on a lower surface of the first semiconductor substrate;
when viewed from above, the trench region is arranged at each vertex of the second semiconductor chips, the trench regions being spaced apart from each other; and
a shape of the trench region is one of a square and a right-angled triangle having at least a portion of the hypotenuse overlapping the second semiconductor chips.
